(19) United States
(12) Patent Application Publication
(10) Pub. No.: US 2006/0234500 A1
(43) Pub. Date: Oct. 19, 2006

(54) Method of forming capacitor of semiconductor device by successively forming a dielectric layer and a plate electrode in a single processing chamber

(76) Inventor: Jong Bum Park, Kyoungki-do (KR)

Correspondence Address: LADAS & PARRY LLP, 224 SOUTH MICHIGAN AVENUE, SUITE 1600, CHICAGO, IL, 60604, US

(21) Appl. No.: 11/302,621

(22) Filed: Dec. 14, 2005

(30) Foreign Application Priority Data
Apr. 15, 2005 (KR) 10-2005-0031298

(51) Int. Cl. H01L 21/4763; H01L 21/302; H01L 21/461

(52) U.S. Cl. 438/648; 438/650; 438/745

(57) ABSTRACT

A capacitor in a semiconductor device is formed by successively forming a dielectric layer and a plate electrode in a single chamber according to an ALD process. The method includes the steps of forming a storage electrode on a semiconductor substrate; loading the semiconductor substrate into an ALD chamber with the storage electrode formed thereon; forming a metal oxide dielectric layer on the storage electrode in the chamber according to an ALD process; and successively forming a metal plate electrode on the metal oxide dielectric layer in the same chamber according to the ALD process.

### BACKGROUND OF THE INVENTION

1. Field of the Invention

The present invention relates generally to a method for manufacturing a capacitor of a semiconductor device, and more particularly to a method for forming a capacitor of a semiconductor device capable of successively forming a dielectric layer and a plate electrode in a single ALD (atomic layer deposition) process chamber.

2. Description of the Prior Art

A capacitor acts as a memory site for storing predetermined data in a memory device, such as a DRAM, and has a dielectric layer interposed between a storage electrode and a plate electrode.

According to prior art, a conventional capacitor is formed by depositing a storage electrode material on a substrate in a chamber, and then the substrate is transferred to another chamber to deposit a dielectric layer on the storage electrode material, and then again the substrate is transferred to yet another chamber to deposit a plate electrode material on the dielectric layer.

However, the above conventional method involves complicated processes, which generally take a long period of time because each of the storage electrode material, dielectric layer, and plate electrode material must be deposited in different chambers. Whenever a substrate is transferred from one chamber to another chamber for processing, native oxide layers and other undesirable contaminants are likely to be created on the surface(s) of the substrate itself and/or on the material layers formed on the substrate in former processes. This will likely degrade the device characteristics.

### SUMMARY OF THE INVENTION

Accordingly, the present invention has been made to solve the above-mentioned problems occurring in the prior art, and an object of the present invention is to provide a method for forming a capacitor of a semiconductor device capable of simplifying processes.

Another object of the present invention is to provide a method for forming a capacitor of a semiconductor device capable of avoiding degradation of device characteristics by preventing both native oxide layers and contaminants from being created on surfaces of material layers, which have been formed in previous processes.

In order to accomplish this object, there is provided a method for forming a capacitor of a semiconductor device including the steps of forming a storage electrode on a semiconductor substrate; loading the semiconductor substrate having the storage electrode formed thereon into an ALD chamber; forming a metal oxide dielectric layer on the storage electrode in the chamber according to an ALD process; and successively forming a metal plate electrode on the metal oxide dielectric layer in the same chamber according to the ALD process.

The storage electrode is formed using n+ doped polysilicon or any metal selected from the group consisting of TiN, Ru, Pt, Ir, HfN, and ZrN.

The storage electrode is formed with a thickness of 50-500 Å.

The method further includes a cleaning step for removing native oxide layers created on a surface of the storage electrode after the step of forming a storage electrode and before the step of loading the semiconductor substrate into an ALD chamber.

The cleaning step is performed using HF or BOE solution, when the storage electrode is made of metal, and using any one selected from the group consisting of HF, BOE, and HF+SC−1, when the storage electrode is made of polysilicon.

The metal oxide dielectric layer is HfO₂ or ZrO₂ layer.

The HfO₂ or ZrO₂ layer is formed by repeating a deposition cycle until a desired thickness is obtained, the deposition cycle comprising the processes of flowing Hf or Zr source gas for 0.1-10 seconds; flowing N₂ gas for 0.1-10 seconds for purging; flowing O₃ reaction gas for 0.1-10 seconds; and flowing N₂ gas for 0.1-5 seconds for purging.

The Hf source gas is any one selected from the group consisting of Hf[NC₂H₅CH₃]₄, Hf[N(CH₃)₂]₄, Hf[OC(CH₃)₂CH₂OCH₃]₄, and Hf[OC(CH₃)₃]₄.

The Zr source gas is ZrCl₄ or ZrI₄.

The metal oxide dielectric layer is formed with a thickness of 30-300 Å under a pressure condition of 0.1-10 Torr and a temperature condition of 25-500° C.

The metal plate electrode is made of HfN or ZrN.

The HfN or ZrN is formed by repeating a deposition cycle until a desired thickness is obtained, the deposition cycle comprising the processes of flowing Hf or Zr source gas for 0.1-20 seconds; flowing N₂ gas for 0.1-20 seconds for purging; flowing NH₃ plasma reaction gas for 0.1-10 seconds; and flowing N₂ gas for 0.1-5 seconds for purging.

The Hf source gas is any one selected from the group consisting of Hf[NC₂H₅CH₃]₄, Hf[N(CH₃)₂]₄, Hf[OC(CH₃)₂CH₂OCH₃]₄, and Hf[OC(CH₃)₃]₄.

The Zr source gas is ZrCl₄ or ZrI₄.

The metal plate electrode is formed with a thickness of 50-500 Å under a pressure condition of 0.1-10 Torr and a temperature condition of 25-500° C.

In accordance with another aspect of the present invention, there is provided a method for forming a capacitor of a semiconductor device including the steps of forming a storage electrode on a semiconductor substrate; loading the semiconductor substrate having the storage electrode formed thereon into an ALD chamber; forming an HfO₂ dielectric layer on the storage electrode in the chamber according to an ALD process; and successively forming an HfN plate electrode in the same chamber according to the ALD process.

In accordance with still another aspect of the present invention, there is provided a method for forming a capacitor of a semiconductor device including the steps of forming a storage electrode on a semiconductor substrate; loading the semiconductor substrate having the storage electrode formed thereon into an ALD chamber; forming an ZrO₂ dielectric layer on the storage electrode in the chamber according to an ALD process; and successively forming an ZrN plate electrode in the same chamber according to the ALD process.

### BRIEF DESCRIPTION OF THE DRAWINGS

The above and other objects, features and advantages of the present invention will be more apparent from the following detailed description taken in conjunction with the accompanying drawings, in which:

FIGS. 1 to 3 are cross-sectional views showing respective processes of a method for forming a capacitor of a semiconductor device according to an embodiment of the present invention.

### DETAILED DESCRIPTION OF THE PREFERRED EMBODIMENTS

Hereinafter, preferred embodiments of the present invention will be described with reference to the accompanying drawings. In the following description and drawings, the same reference numerals are used to designate the same or similar components, and so repetition of the description on the same or similar components will be omitted.

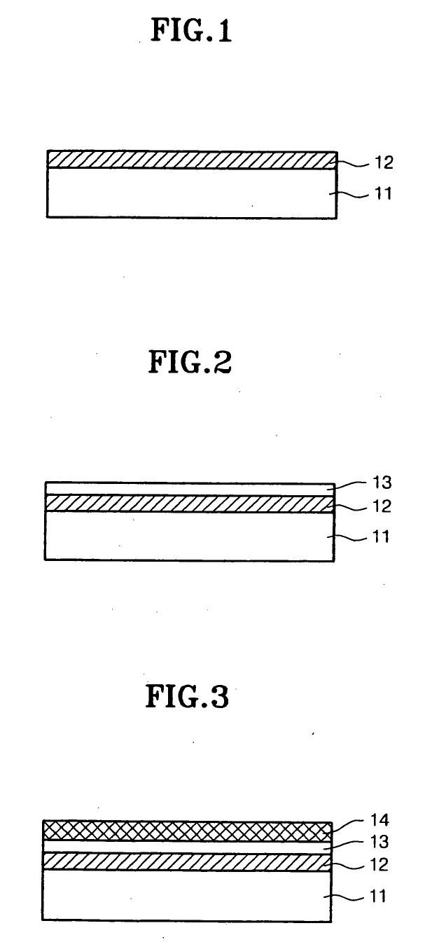

FIGS. 1 to 3 are cross-sectional views showing the processes in a method of forming a capacitor in a semiconductor device according to an embodiment of the present invention.

Referring to FIG. 1, a storage electrode 12 is formed on a semiconductor substrate 11, which has a primer layer formed thereon, using n+ doped polysilicon or any metal selected from TiN, Ru, Pt, Ir, HfN, and ZrN with a thickness of 50-500 Å. After the storage electrode 12 is formed, the substrate is cleaned to remove native oxide layers from surfaces of the storage electrode 12.

In the cleaning process, HF or BOE solution is used if the storage electrode 12 is made of metal. HF, BOE, or HF+SC−1(NH₄OH+H₂O₂+H₂O) solution is used for cleaning if the storage electrode 12 is made of polysilicon.

Although the storage electrode 12 has a planar structure in the present embodiment, other structures including concave and cylindrical structures may be used.

Referring to FIG. 2, the semiconductor substrate 11 is loaded into an atomic layer deposition (ALD) chamber to form a metal oxide dielectric layer 13 on the storage electrode 12 in an ALD process to form a layer of HfO₂ or ZrO₂.

Specifically, the processes for forming the metal oxide dielectric layer 13 of HfO₂ or ZrO₂ are as follows:

(1) Hf or Zr source gas is flowed for 0.1-10 seconds to form an Hf or Zr atomic layer on the surface of the storage electrode 12;

(2) N₂ gas is flowed for 0.1-10 seconds to purge the source gas, which has not reacted;

(3) O₃ reaction gas is flowed for 0.1-10 seconds to form an oxygen atomic layer; and

(4) N₂ gas is flowed for 0.1-5 seconds to purge the reaction gas, which has not reacted. These four processes constitute a deposition cycle, which is repeated until a desired thickness is obtained to form a final dielectric layer 13.

For Hf source gas, any one of Hf[NC₂H₅CH₃]₄, Hf[N(CH₃)₂]₄, Hf[OC(CH₃)₂CH₂OCH₃]₄, and Hf[OC(CH₃)₃]₄ can be used. For Zr source gas, ZrCl₄ or ZrI₄ can be used. The HfO or ZrO₂ layer is formed with a thickness of 30-300 Å under a pressure condition of 0.1-10 Torr and a temperature condition of 25-500° C.

Referring to FIG. 3, a metal plate electrode 14 is successively formed on the metal oxide dielectric layer 13 to form a layer of HfN or ZrN in the same chamber according to the ALD process.

Specifically, processes for forming HfN or ZrN layer are performed as follows:

(1) Hf or Zr source gas is flowed for 0.1-20 seconds to form an Hf or Zr atomic layer 14a;

(2) N₂ gas is flowed for 0.1-20 seconds to purge source gas, which has not reacted;

(3) NH₃ plasma reaction gas is flowed for 0.1-10 seconds to form a nitrogen atomic layer 14b; and

(4) N₂ gas is flowed for 0.1-5 seconds to purge reaction gas, which has not reacted. These four processes constitute a deposition cycle, which is repeated until a desired thickness is obtained to form a plate electrode 14.

In forming the plate electrode 13, the same Hf source gas and Zr source gas that were used to form the dielectric layer 13 are used. The metal plate electrode is formed with a thickness of 50-500 Å under the same pressure and temperature conditions as when the metal oxide dielectric layer is formed.

When the NH₃ plasma is used as a reaction gas in forming HfN, C included in the source gas for forming HfO₂ is coupled to H+ and volatilized. This improves the quality of HfO₂ layer. Even when HfO₂ is deposited at a low temperature, its thin layer still crystallizes. However, by subjecting the crystallized HfO₂ dielectric layer to NH₃ plasma treatment, it becomes amorphous. This reduces the amount of leak current, which has been flowing through grain boundaries of crystallized HfO₂, and improves device characteristics.

In summary, according to the present invention, a dielectric layer and a plate electrode are successively deposited in the same chamber that has been used to deposit a storage electrode, without moving the substrate. This prevents both native oxide layers and contaminants from being created on the dielectric layer.

As mentioned above, the present invention is advantageous in that a dielectric layer and a plate electrode can be successively deposited in the same chamber that has been used to deposit a storage electrode to prevent both native oxide layers and contaminants from being created on the dielectric layer and improve device characteristics.

Since a single chamber is used to form both the dielectric layer and the plate electrode of a capacitor in the same deposition method, the initial investment for equipment becomes less and the process time is shorted. In addition, the amount of utilities necessary for processing is reduced. All these collectively decrease the overall cost.

Although a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A method of forming a capacitor of a semiconductor device comprising the steps of:
forming a storage electrode on a semiconductor substrate;
loading the semiconductor substrate into an ALD chamber with the storage electrode formed thereon;
forming a metal oxide dielectric layer on the storage electrode in the ALD chamber according to an ALD process; and
successively forming a metal plate electrode on the metal oxide dielectric layer in the same ALD chamber according to the ALD process.

2. The method as claimed in claim 1, wherein the storage electrode is formed using n+ doped polysilicon or any one of TiN, Ru, Pt, Ir, HfN, and ZrN.

3. The method as claimed in claim 1, wherein the storage electrode is formed with a thickness of 50-500 Å.

4. The method as claimed in claim 1, further comprising a cleaning step of removing native oxide layers created on a surface of the storage electrode performed after the step of forming a storage electrode and before the step of loading the semiconductor substrate into an ALD chamber.

5. The method as claimed in claim 4, wherein the cleaning step is performed using HF or BOE solution when the storage electrode is made of metal.

6. The method as claimed in claim 4, wherein the cleaning step is performed using one of HF, BOE, and HF+SC−1 when the storage electrode is made of polysilicon.

7. The method as claimed in claim 1, wherein the metal oxide dielectric layer is a HfO₂ layer or a ZrO₂ layer.

8. The method as claimed in claim 7, wherein the HfO₂ or ZrO₂ layer is formed by repeating a deposition cycle until a desired thickness is obtained, the deposition cycle comprising:
flowing a Hf or Zr source gas for 0.1-10 seconds;
flowing a N₂ gas for 0.1-10 seconds for purging;
flowing a O₃ reaction gas for 0.1-10 seconds; and
flowing a N₂ gas for 0.1-5 seconds for purging.

9. The method as claimed in claim 8, wherein the Hf source gas is one of Hf[NC₂H₅CH₃]₄, Hf[N(CH₃)₂]₄, Hf[OC(CH₃)₂CH₂OCH₃]₄, and Hf[OC(CH₃)₃]₄.

10. The method as claimed in claim 8, wherein the Zr source gas is ZrCl₄ or ZrI₄.

11. The method as claimed in claim 1, wherein the metal oxide dielectric layer is formed with a thickness of 30-300 Å under a pressure condition of 0.1-10 Torr and a temperature condition of 25-500° C.

12. The method as claimed in claim 1, wherein the metal plate electrode is made of HfN or ZrN.

13. The method as claimed in claim 12, wherein the HfN or ZrN is formed by repeating a deposition cycle until a desired thickness is obtained, the deposition cycle comprising the processes of:
flowing a Hf or Zr source gas for 0.1-20 seconds;
flowing a N₂ gas for 0.1-20 seconds for purging;
flowing a NH₃ plasma reaction gas for 0.1-10 seconds; and
flowing a N₂ gas for 0.1-5 seconds for purging.

14. The method as claimed in claim 13, wherein the Hf source gas is one of Hf[NC₂H₅CH₃]₄, Hf[N(CH₃)₂]₄, Hf[OC(CH₃)₂CH₂OCH₃]₄, and Hf[OC(CH₃)₃]₄.

15. The method as claimed in claim 13, wherein the Zr source gas is ZrCl₄ or ZrI₄.

16. The method as claimed in claim 1, wherein the metal plate electrode is formed with a thickness of 50-500 Å under a pressure condition of 0.1-10 Torr and a temperature condition of 25-500° C.

17. A method for forming a capacitor of a semiconductor device comprising the steps of:
forming a storage electrode on a semiconductor substrate;
loading the semiconductor substrate having the storage electrode formed thereon into an ALD chamber;
forming an HfO₂ dielectric layer on the storage electrode in the same ALD chamber according to an ALD process; and
successively forming an HfN plate electrode in the same ALD chamber according to the ALD process.

18. A method for forming a capacitor of a semiconductor device comprising the steps of:
forming a storage electrode on a semiconductor substrate;
loading the semiconductor substrate having the storage electrode formed thereon into an ALD chamber;
forming an ZrO₂ dielectric layer on the storage electrode in the same ALD chamber according to an ALD process; and
successively forming an ZrN plate electrode in the same ALD chamber according to the ALD process.
